(19) United States
(12) Patent Application Publication
(10) Pub. No.: US 2018/0119929 A1
(43) Pub. Date: May 3, 2018

(54) CONCRETE CASTING SYSTEM AND A METHOD FOR PROVIDING A LIGHTING SYSTEM IN A BUILDING

(71) Applicant: OSRAM GmbH, Munich (DE)

(72) Inventors: Herbert Weiss, Diedorf (DE); Gerhard Doell, Stuttgart (DE)

(21) Appl. No.: 15/566,737

(22) PCT Filed: Mar. 21, 2016
(86) PCT No.: PCT/EP2016/056084

§ 371 Date: Oct. 16, 2017

(30) Foreign Application Priority Data
Apr. 17, 2015 (DE) 10 2015 207 005.0

(51) Int. Cl. F21V 19/00; E04B 5/32; E04G 17/00; H05K 5/04; H05K 5/03; H02G 3/04; H02G 3/00; F21K 9/237; F21S 8/02; F21V 33/00

(52) U.S. Cl. CPC F21V 19/005; E04B 5/32; E04G 17/00; H05K 5/04; H05K 5/03; F21Y 2115/10; H02G 3/26; F21K 9/237; F21S 8/026; F21V 33/006; E04B 2103/02; H02G 3/0462

(57) ABSTRACT

According to the present disclosure, a concrete casting system including a large number of individual concrete casting boxes is provided. The concrete casting system has a grid-like structure in which the individual concrete casting boxes are arranged at the intersection points of the grid-like structure. Two respectively adjacent concrete casting boxes are connected to one another by means of a spacer. Each concrete casting box has a housing which has at least one opening in a direction perpendicular to the direction of extent of the grid-like structure. The concrete casting system is designed such that it can be rolled up or folded.

### RELATED APPLICATIONS

The present application is a national stage entry according to 35 U.S.C. § 371 of PCT application No.: PCT/EP2016/056084 filed on Mar. 21, 2016, which claims priority from German application No.: 10 2015 207 005.0 filed on Apr. 17, 2015, and is incorporated herein by reference in its entirety.

### TECHNICAL FIELD

The present disclosure relates to a concrete casting system. Moreover, said present disclosure relates to a method for providing a lighting system in a building.

### BACKGROUND

Concrete casting boxes which, when they are of round design, also called concrete casting pots are known from the prior art. A typical example is available under the name BTES 3.135 from LTS-Licht&Leuchten GmbH, Tettnang, Germany. This concrete casting pot is designed for exposed concrete and is suitable for stainless steel downlights with a diameter D=197 mm and an installation depth of at most 135 mm. The concrete casting pot is fastened by indirect screw connection on the formwork, wherein no fastening parts are visible on the ceiling. The housing is composed of galvanized metal, the physical shape is, as mentioned, round and further includes a centering cover.

During mounting, the reinforcement at the point at which a concrete casting box of this kind is provided is cut out and the concrete casting box is fixed at this point. Individual boxes are connected to the power supply access and to one another by empty conduits. The boxes are electrically wired to a power supply system and to one another individually after being cast in concrete.

If a room is intended to be illuminated using a relatively large number of downlights, the use of concrete casting boxes according to the prior art entails considerable installation work and therefore expense.

### SUMMARY

The object of the present disclosure is therefore to provide a concrete casting system which allows cost-effective and multipurpose installation of a large number of downlights which is simple to carry out.

A further object is to provide a corresponding method for providing a lighting system in a building.

These objects are achieved by a concrete casting system having the features of patent claim 1 and also by a method for providing a lighting system in a building having the features of patent claim 18.

The present disclosure is based on the finding that the installation work can be considerably reduced when a large number of individual concrete casting boxes are combined in a grid-like structure. According to the present disclosure, it is therefore provided that the concrete casting system has a grid-like structure in which the individual concrete casting boxes are arranged at the intersection points of the grid-like structure. Two respectively adjacent concrete casting boxes are connected to one another by means of a spacer. The spacers form the grid-like structure. The length of the spacers, that is to say the distances between the individual concrete casting boxes, is advantageously between 10 cm and 2 m, particularly advantageously 60 cm. Each concrete casting box has a housing which has at least one opening in a direction perpendicular to the direction of extent of the grid-like structure. A downlight can then be arranged in said opening or is already arranged in said opening. Usually, between 0.3 and 10, particularly advantageously 2-3, concrete casting boxes are provided per m².

In the case of the method according to the present disclosure, a concrete casting system including a large number of individual concrete casting boxes is initially provided, wherein the concrete casting system has a grid-like structure in which the individual concrete casting boxes are arranged at the intersection points of the grid-like structure, wherein two respectively adjacent concrete casting boxes are connected to one another by means of a spacer, wherein each concrete casting box has a housing which has at least one opening in a direction perpendicular to the direction of extent of the grid-like structure, wherein a cover is fitted onto the opening. The concrete casting system is then inserted into formwork. In a following step, a steel reinforcement is inserted into the formwork. Subsequently, the formwork is filled with concrete. The formwork is then removed and the cover is removed from at least one opening of a concrete casting box.

The present disclosure allows a large number of concrete casting boxes to be laid as a connected grid, as a result of which the installation of individual concrete casting boxes is avoided. This results in considerably less installation work, as a result of which the costs of installation can be reduced to a considerable extent.

Laying said concrete casting boxes as a grid has the advantage that downlights can be installed for an entire floor or at least for an entire room by rolling out a grid-like concrete casting system according to the present disclosure and then fixing said grid-like concrete casting system on the formwork once. Boxes and empty conduits therefore no longer need to be laid individually.

At least one of the spacers advantageously has a tubular structure which is designed, in particular, in the form of a tube. This provides the option, in principle, for the electrical apparatuses, for example lighting means, which are arranged in the individual concrete casting boxes to make contact with one another in a simple manner as required since, given a corresponding design of the tubular structure, electrical lines can be subsequently pushed through said tubular structure in a simple manner. Therefore, a selection of individual concrete casting boxes or else all of the concrete casting boxes can be wired subsequently, that is to say even after being cast in concrete, without problems.

In this context, a particularly preferred embodiment is distinguished in that an electrical line for supplying power is already arranged at least in one spacer at the factory. At least one further electrical or optical line is advantageously arranged in the same spacer. A further electrical or optical line can also be arranged in another spacer. In this case, the further electrical or optical line can serve to transmit a control signal to a lighting means which is arranged in the concrete casting box, for example for adjusting a brightness or a color locus. Conversely, sensors, such as temperature sensors, brightness sensors, WLAN nodes and the like for example, can also be arranged in the concrete casting box and the signals from said sensors can be transmitted to an associated control apparatus by means of the further electrical or optical line.

Since an electrical line for supplying power is already accommodated at least in the one spacer, the wiring operation can already be performed at the factory, as a result of which the installation work can be further reduced. The concrete casting boxes have corresponding openings for the spacers which are in the form of a tube, so that the tubes can be coupled to the concrete casting boxes and the cable can be inserted into the concrete casting box via the opening through the tube, in order to allow contact to be made with a lamp.

At least one tubular spacer is advantageously associated with each concrete casting box, it being possible for an electrical line for supplying power to be arranged in said tubular spacer or said electrical line already being arranged therein. This ensures that a lighting means or a lamp which can be arranged or is already arranged in the concrete casting box can be connected to the power supply.

At least one of the spacers particularly advantageously has a rod-like structure which is designed, in particular, in the form of an insulated wire or in the form of a plastic rod. In this way, dimensional stability of the rod-like structure is provided at least in one dimension, said dimensional stability making it easier to lay the grid-like structure. However, it is not necessary for all of the spacers to be of rod-like design in this dimension in order to ensure dimensional stability. In order to ensure that the concrete casting boxes are wired to one another, the spacers required for this purpose can be of tubular design. If the concrete casting system is designed such that it can be rolled up or folded, the changeover from the transportation state to the installation state can also be considerably simplified owing to the dimensional stability since tangling or twisting of the grid-like structure is largely prevented.

In connection with a design of the concrete casting system according to the present disclosure such that it can be rolled up or folded, at least the spacers which are oriented in one direction are of flexible design and/or the coupling of the spacers to the concrete casting boxes is of articulated design.

The housing of a concrete casting box can be metallic and/or can be formed from a plastic. A metallic design is preferred for relatively high power classes since this allows particularly effective heat transfer from the housing base to the concrete, whereas a design from plastic is preferred particularly when a transmitter and/or a receiver is intended to be arranged in the housing.

It has found to be particularly advantageous when the size of the concrete casting boxes used is considerably reduced in comparison to the prior art, as a result of which each box has a low space requirement and lower costs. A concrete casting box particularly advantageously has a depth in the opening direction, which depth is at most 3 cm, advantageously at most 2 cm. For reasons of corrosion protection for the reinforcement, said reinforcement should be fitted at least 1.5 cm behind the ceiling surface. However, the reinforcement is usually fitted at a distance of at least 3 cm from the ceiling surface. Therefore, concrete casting boxes with the preferred depth mentioned can be used in reinforcements with customary depths without problems. Owing to this low depth, the box is lower than the installation depth of the lattice-like steel reinforcement usually used. As a result, any desired coherent concrete casting boxes, that is to say concrete casting boxes which are connected to one another by previously prefabricated connections or spacers, can be laid before the concrete casting operation, without the reinforcement having to be cut out for this purpose as is customary in the prior art.

In addition to lighting means, other built-in ceiling elements which have to be supplied with electric current, for example sensors, can also be installed in the concrete casting boxes, as mentioned.

In respect of its shape in plan view, that is to say in particular also the shape of the opening, concrete casting boxes according to the present disclosure can be angular, round or elliptical, that is to say the cross section of a concrete casting box can be angular, round or elliptical perpendicular to the opening direction. A round design is particularly preferred, wherein the diameter of a concrete casting box of this kind is between 10 mm and 20 cm, advantageously between 10 mm and 75 mm. Whereas downlights according to the prior art have a diameter of between approximately 80 mm and 250 mm depending on the power class, the present disclosure allows economic mounting even with concrete casting boxes with a diameter which is considerably reduced in comparison with the prior art. If a diameter which is smaller in this way is selected and a very small lamp, for example with only one LED, is provided for each casting box, a so-called “starry sky” effect can be realized, that is to say a large number of, in particular even irregularly distributed, individual light sources on the ceiling of a room. The irregularity is made possible by irregularly distributed casting boxes being left without a lighting means being fitted or by the cover not being removed from the opening of the concrete casting box, even if a lighting means is already arranged in the box.

At least one lamp can be arranged in the housing. The lamp can have at least one LED. The lamp advantageously does not have any heat sinks for the LED. In order to be able to dispense with a heat sink even in the case of high power classes, it is preferred when measures are taken in order to improve the heat transfer to the concrete. Apparatuses for spreading heat in particular come into consideration here, for example metallic elements which are arranged on the base of the housing, that is to say opposite the opening, and advantageously have a larger surface than the base of the housing. The depth of apparatuses of this kind for spreading heat can be kept low, for example ≤5 mm.

As an alternative to the variant in which at least one lamp, advantageously with at least one LED, is already arranged in the housing, a fastening mechanism for fastening and/or making contact with a lamp can be arranged in the housing. The fastening mechanism may include, in particular, cable clamps and/or at least one plug connection and/or at least one screw connection. In this way, specific concrete casting boxes can be equipped with lighting means or lamps in a targeted manner, while others remain unequipped. Since the lighting means used also constitute a cost factor, the costs can be reduced as a result. Particularly in this context, it is expedient for the concentration of the concrete casting boxes of the grid-like structure, that is to say the distances of said concrete casting boxes from one another, to be small, that is to say between 10 cm and 20 cm for example, and then for only these desired concrete casting boxes to be equipped with lighting means.

Each concrete casting box advantageously includes a detachable cover for the opening. The cover is advantageously designed with a shape and size such that it exposes an opening which corresponds in size and shape to the lamp to be inserted. As an alternative, the cover can be designed such that it is not removed from the opening, but rather only a hole which matches the lamp to be inserted in terms of size and shape is removed from the cover. The cover firstly ensures, in principle, that the interior of the housing is not contaminated when the concrete is cast, and secondly that the concrete casting boxes which are intended to be equipped or those which are already equipped at the factory and are provided for irradiating light can be exposed in a simple manner. In this context, it is particularly preferred that at least one cover includes at least one electrical bridging arrangement which is designed in such a way that, when a cover is mounted onto the housing, bridging of at least two electrical contacts which project into the housing is implemented. It goes without saying that the cover can be designed in such a way that electrical bridging of a plurality of contact pairs is possible, for example ground line, power supply, control line, sensor line and the like. Therefore, through-plating of the lines in question is ensured when the cover is mounted on the housing.

According to a preferred development, a radio receiver and/or a radio transmitter can be arranged in at least one housing. In this way, measurement signals can be emitted from the concrete casting box or, for example for the purpose of controlling the lamp, transmitted to the respective concrete casting box in a wireless manner. As already mentioned, at least one sensor, in particular a smoke alarm and/or a fire alarm, can also be arranged in at least one housing.

Further preferred embodiments can be gathered from the dependent claims.

The preferred embodiments presented with reference to the concrete casting system according to the present disclosure and the advantages of said embodiments correspondingly apply, if applicable, to the method according to the present disclosure for providing a lighting system in a building too.

### BRIEF DESCRIPTION OF THE DRAWING(S)

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic illustration of an exemplary embodiment of a concrete casting system according to the present disclosure in the unrolled or unfolded state;

FIG. 2 shows a schematic illustration of an exemplary embodiment of a concrete casting system according to the present disclosure in a partially rolled-up state;

FIG. 3 shows a cross section through a concrete ceiling with reinforcement and a concrete casting system according to the present disclosure installed; and

FIGS. 4A and 4B show a schematic illustration of an embodiment of a concrete casting box as is used in a concrete casting system according to the present disclosure.

### DETAILED DESCRIPTION

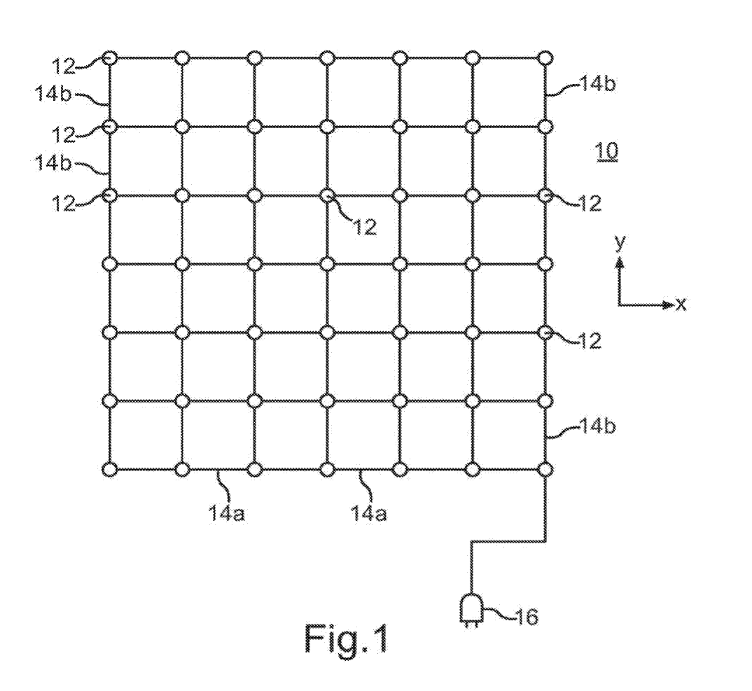

FIG. 1 shows a schematic illustration of an exemplary embodiment of a concrete casting system 10 according to the present disclosure having a large number of concrete casting boxes 12 which are arranged at the intersection points of the grid-like structure. The respectively adjacent concrete casting boxes are likewise mechanically, advantageously mechanically and electrically, coupled to one another by means of spacers 14a in the x-direction and 14b in the y-direction. To this end, the spacers 14a, 14b advantageously have a tubular structure in which, if required, an electrical line for supplying power or further electrical or optical lines can be arranged. The spacers 14a, 14b can, in particular, be in the form of an insulated wire or in the form of a plastic rod. The connection to a power supply is schematically indicated by 16. Said power supply can constitute, in particular, an AC power supply system.

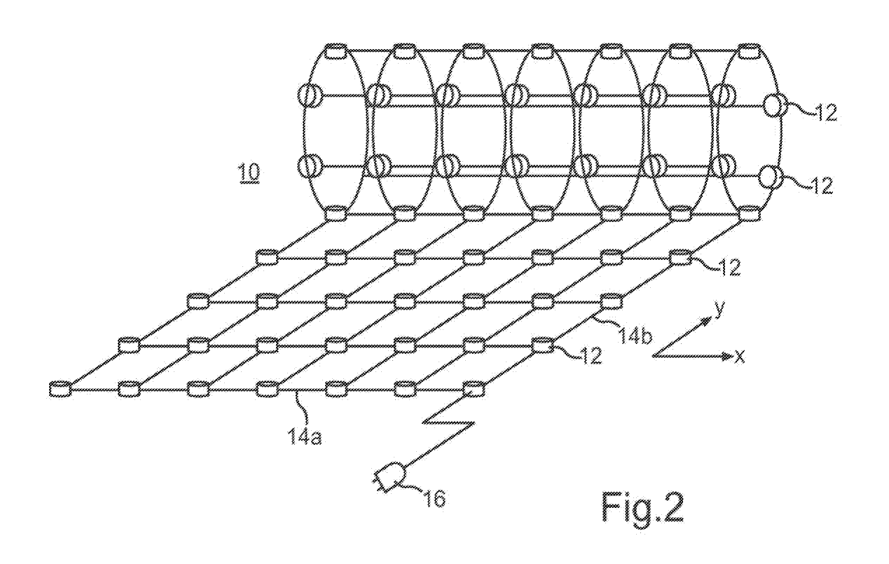

FIG. 2 shows the concrete casting system 10 according to the present disclosure in a partially rolled-up state. In order to make this possible, at least the spacers 14b in the y-direction are of flexible design. As an alternative, the corresponding coupling of the spacers 14b to the concrete casting boxes 12 could also be of articulated design and the spacers 14b themselves could be stiffer than in the embodiment illustrated in FIG. 2.

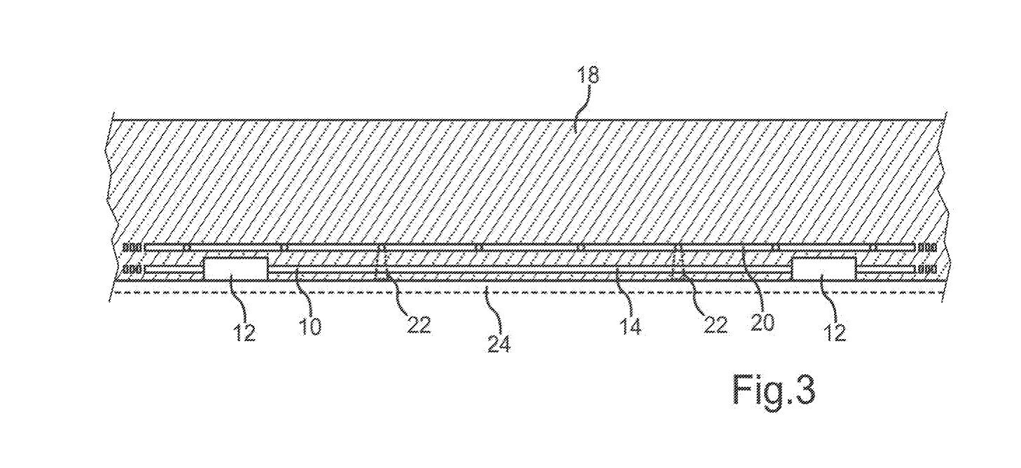

FIG. 3 shows a schematic illustration of a cross section through a concrete ceiling 18 in which a concrete casting system 10 according to the present disclosure for realizing a lighting system in a building is arranged. A steel reinforcement 20 which is arranged in the concrete ceiling 18 is supported against formwork 24, illustrated using a dashed line, by means of spacers 22. Before the reinforcement 20 was inserted, a concrete casting system 10 according to the present disclosure including spacers 14 and concrete casting boxes 12 was arranged on the formwork 24 in the present case. As is clearly shown, the depth of a casting box 12 in a direction perpendicular to the concrete ceiling 18 is smaller than the distance between the formwork 24 and the reinforcement 20. Therefore, it is possible to dispense with cutting out regions of the reinforcement 20 in order to create space for concrete casting boxes 12.

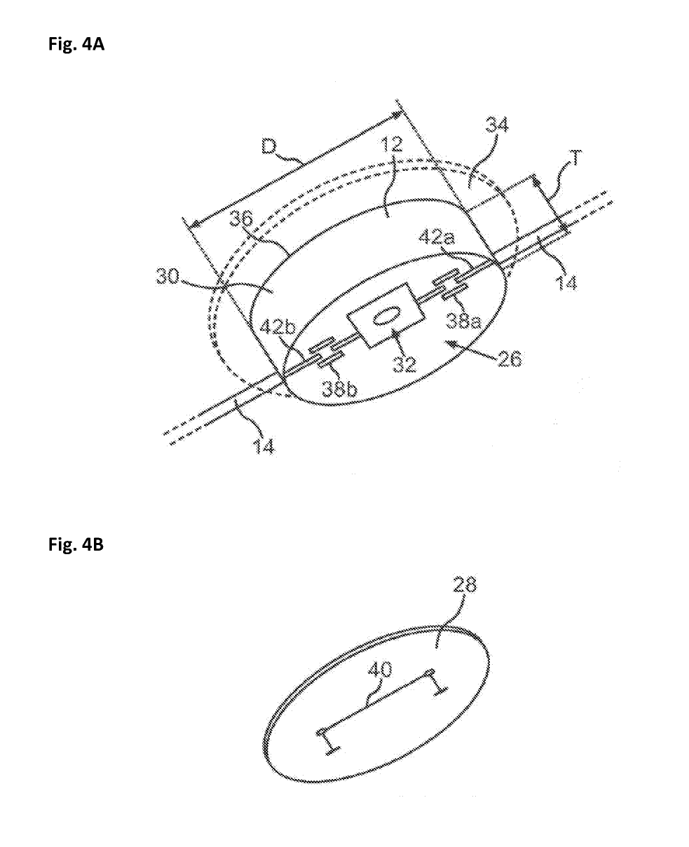

FIGS. 4A and 4B show a schematic illustration of an embodiment of a concrete casting box 12 according to the present disclosure, wherein the casting box 12 which is arranged between two spacers 14 and has an open opening 26 is illustrated in FIG. 4A and a cover 28 which closes the opening 26 during casting with concrete is illustrated in FIG. 4B.

The housing 30 of the concrete casting box 12 can be formed from metal and/or from plastic. The depth T in the opening direction is at most 3 cm, advantageously at most 2 cm. Although the concrete casting box 12 is round in the exemplary embodiment, it can also be of angular or elliptical design. In the case of a round design of the concrete casting box 12, the diameter D is between 10 mm and 20 cm, advantageously between 10 mm and 75 mm. In the case of angular or elliptical design, these dimensions apply to the edge length and, respectively, the smaller of the two diameters.

In the present case, an LED 32 is arranged as lighting means in the housing 30, wherein the lamp formed by said LED does not have a heat sink for the LED 32. As indicated using dashed lines, a metallic disc 34 which is arranged on the base 36 of the housing 30 can be used in order to spread heat. The LED 32 can already be permanently wired in the housing 30. However, it is also possible, as schematically illustrated here, for a fastening mechanism for fastening and/or making contact with a lamp to be provided, said fastening element including, for example, plug connections 38a, 38b. As an alternative, cable clamps or screw connections can also be provided.

In order to install, for example, an LED or lamp, the cover 28 is removed from the housing opening 26 and a correspondingly contacted LED or lamp 32 is inserted into the plug connections 38a, 38b.

As already mentioned, the cover 28 is of detachable design. In the exemplary embodiment, said cover includes an electrical bridging arrangement 40 which is designed in such a way that, by virtue of a cover 28 which is mounted onto the housing 30, bridging of the contacts 42a, 42b which project into the housing 30 is implemented.

A radio receiver and/or a radio transmitter and/or a sensor, in particular a smoke alarm and/or a fire alarm, can also be arranged in the housing 30.

The casting boxes 12 are advantageously already wired to one another from the factory. A cable length between the boxes which is designed with the typical grid pattern, for example 60 cm×60 cm, or else is designed to be shorter or longer is advantageously selected.

The concrete casting system according to the present disclosure which includes a grid of wired boxes 12 can already be mounted on a roll at the factory, so that space-saving storage and simple transportation are possible. The concrete casting system 10 can be laid at the installation site by simply unrolling the roll onto the formwork 24. In this case, the thickness and durability of the wiring arrangement are designed such that said wiring arrangement can withstand being cast in concrete. As already mentioned, an empty conduit arrangement can also serve for connection, cables already being passed through said empty conduit arrangement at the factory or cables being passed through said empty conduit arrangement subsequently. This has the advantage that further cables can also be drawn through the conduits, for example for loudspeakers, fire alarms or the like, subsequently.

The concrete casting boxes 12 are designed such that the lamps 32 can be electrically connected by cable clamps or plugs 38a, 38b. The lamp can be reliably prevented from falling out of the box 12 by a correspondingly designed plug-connection mechanism and a correspondingly designed screw connection.

Laying the concrete casting system 10 allows installation locations to be kept for downlights. It is advantageous when the grid is designed more densely than the density at which downlights are intended to be installed. Therefore, virtually any desired arrangement of downlights can be realized and downlights can be, as it were, repositioned subsequently.

The unused housings 36 are each provided with a covering cap 28 which allows said housings to be closed off with the concrete ceiling surface as far as possible without joints. In order to ensure electrical bridging, cables are clamped together or connected by means of plugs in the boxes without downlights. The preferred solution is, as mentioned, illustrated in FIG. 4B and includes a bridging contact 40 which connects the connections 42a, 42b to one another when the covering cap 28 is mounted.

The concrete casting boxes 12 can also be designed with an electromechanical interface such that, in addition to the lamp 32 and the bridging contact 40, other functions which require the supply of electric current and electrical signals, such as sensors, fire alarms, smoke alarms for example, can also be realized. Particularly when using an electrically nonconductive housing 30, it is possible for wireless radio communication, for example ZigBee, to be realized for the signals together with the lighting function, and for only the power supply system to be supplied by means of a cable power supply system.

As already mentioned, it is particularly advantageous when the lamps 32 are already integrated into the networked concrete casting boxes 12 at the factory. This has the advantage that the electrical connection can already be made at the factory and does not have to be performed in an awkward manner at the ceiling. Installation time and therefore installation costs can be further reduced as a result. The lamps 32 are advantageously provided with a protective film at the factory, said protective film preventing damage during concrete casting operations and it being possible for said protective film to be removed after the casting operation.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A concrete casting system comprising a large number of individual concrete casting boxes,
wherein the concrete casting system has a grid-like structure in which the individual concrete casting boxes are arranged at the intersection points of the grid-like structure,
wherein two respectively adjacent concrete casting boxes are connected to one another by means of a spacer,
wherein each concrete casting box has a housing which has at least one opening in a direction perpendicular to the direction of extent of the grid-like structure, and
wherein the concrete casting system is designed such that it can be rolled up or folded.

2. The concrete casting system as claimed in claim 1,
wherein at least one of the spacers has a tubular structure.

3. The concrete casting system as claimed in claim 2,
wherein an electrical line for supplying power is arranged at least in one spacer.

4. The concrete casting system as claimed in claim 1,
wherein at least one of the spacers has a rod-like structure.

5. The concrete casting system as claimed in claim 2,
wherein at least one tubular spacer is associated with each concrete casting box.

6. (canceled)

7. The concrete casting system as claimed in claim 1,
wherein at least the spacers which are oriented in one direction are of flexible design and/or the coupling of the spacers to the concrete casting boxes is of articulated design.

8. The concrete casting system as claimed in claim 1,
wherein the housing of a concrete casting box is metallic and/or is formed from a plastic.

9. The concrete casting system as claimed in claim 1,
wherein a concrete casting box has a depth in the opening direction, which depth is at most 3 cm.

10. The concrete casting system as claimed in claim 1,
wherein the cross section of a concrete casting box is angular, round or elliptical perpendicular to the opening direction.

11. The concrete casting system as claimed in claim 1,
wherein the cross section of the concrete casting box is round perpendicular to the opening direction, wherein the diameter of the concrete casting box is between 10 mm and 20 cm.

12. The concrete casting system as claimed in claim 1,
wherein at least one lamp with at least one LED is arranged in the housing.

13. The concrete casting system as claimed in claim 1,
wherein a fastening mechanism for fastening a lamp is arranged in the housing.

14. The concrete casting system as claimed in claim 1,
wherein each concrete casting box comprises a detachable cover for the opening.

15. The concrete casting system as claimed in claim 14,
wherein at least one cover comprises at least one electrical bridging arrangement which is designed in such a way that, when a cover is mounted onto the housing, bridging of at least two electrical contacts which project into the housing is implemented.

16. The concrete casting system as claimed in claim 1,
wherein a radio receiver and/or a radio transmitter are/is arranged in at least one housing.

17. The concrete casting system as claimed in claim 1,
wherein at least one sensor is arranged in at least one housing.

18. A method for providing a lighting system in a building, comprising:
providing a concrete casting system comprising a large number of individual concrete casting boxes, wherein the concrete casting system has a grid-like structure in which the individual concrete casting boxes are arranged at the intersection points of the grid-like structure, wherein two respectively adjacent concrete casting boxes are connected to one another by means of a spacer, wherein each concrete casting box has a housing which has at least one opening in a direction perpendicular to the direction of extent of the grid-like structure, wherein a cover is fitted onto the opening;
inserting the concrete casting system into formwork;
inserting a steel reinforcement into the formwork;
filling the formwork with concrete;
removing the formwork; and
removing the cover from at least one opening of a concrete casting box.
